(19) United States
(12) Patent Application Publication
(10) Pub. No.: US 2012/0302026 A1
(43) Pub. Date: Nov. 29, 2012

(54) METHOD FOR FORMING A TRANSISTOR

(75) Inventor: Meng ZHAO, Shanghai (CN)

(73) Assignee: Semiconductor Manufacturing International (Shanghai) Corporation, Shanghai (CN)

(21) Appl. No.: 13/274,275

(22) Filed: Oct. 14, 2011

(30) Foreign Application Priority Data
May 25, 2011 (CN) 201110136713.7

(51) Int. Cl. H01L 21/336

(52) U.S. Cl. 438/290; 438/289; 257/E21.444; 257/E21.394

(57) ABSTRACT

A method for forming a transistor includes providing a substrate, forming a well region in the substrate, and forming a gate structure on a surface of the well region. The gate structure includes a gate oxide layer on the surface of the well region and a gate on the gate oxide layer. The method further includes forming source/drain regions in the substrate at opposite sides of the gate structure and performing an ion doping to the substrate to adjust a threshold voltage. The ion doping is performed after the source/drain regions are formed to reduce the impact to the diffusion of the ions caused by heat treatments performed before the ion doping. The method further includes heating the substrate after the ion doping at a temperature from about 400° C. to about 500° C.

### CROSS-REFERENCES TO RELATED APPLICATIONS

The present application claims the priority of Chinese Patent Application No. 201110136713.7, entitled “METHOD FOR FORMING A TRANSISTOR”, filed on May 25, 2011, the entire disclosure of which is incorporated herein by reference.

### FIELD OF THE INVENTION

The present invention generally relates to the semiconductor field, and more particularly, to a method for forming a transistor having lower junction capacitance and improved switching performance.

### BACKGROUND OF THE INVENTION

Metal-Oxide-Semiconductor (MOS) transistors are the most fundamental devices in semiconductor manufacturing processes and are widely used in various integrated circuits. MOS transistors are divided into NMOS transistors and PMOS transistors according to the major carriers and doping types thereof.

FIGS. 1 to 3 are schematic cross-sectional views of intermediate structures of a conventional method for forming a MOS transistor.

Referring to FIG. 1, a substrate 01 is provided. An ion implantation process and then a heat treatment process are performed to the substrate 01 to form a well region 001. Another ion implantation process is performed to the substrate 01 to form a doped region 002. The doped region 002 is under a surface area of the substrate 01 and is used to adjust a threshold voltage. A gate oxide layer 02 and a gate 03 are formed on the substrate 01. The gate oxide layer 02 and the gate 03 together form a gate structure.

Then, lightly doped regions 04 are formed in the substrate 01 at opposite sides of the gate structure, as shown in FIG. 2. The lightly doped regions 04 are formed by an ion implantation process and a heat treatment process.

Thereafter, spacers 05 are formed on the substrate 01 and sidewalls of the gate structure. Using the spacers 05 as a mask, a heavily doped implantation process and then a heat treatment process are performed to the substrate 01 to form source/drain (S/D) regions 06.

It is found that the junction capacitance and the junction current between the source/drain regions and the substrate of the transistor formed by the conventional method are relatively large, and the performance of the transistor is low.

### BRIEF SUMMARY OF THE INVENTION

An object of the present invention is to provide a method for forming a transistor that reduces the junction capacitance between the source/drain regions and the substrate and the junction leaking current, thus, improving the operation speed and the performance of the transistor.

Embodiments of the present invention provide methods for forming a transistor. According to an embodiment of the present invention, a method for forming a transistor includes providing a substrate, forming a well region in the substrate, and forming a gate structure on a surface area of the substrate, wherein the gate structure includes a gate oxide layer disposed on a surface area of the well region and a gate disposed on the gate oxide layer. The method further includes forming source/drain regions in the substrate at opposite sides of the gate structure, and performing a first implantation process to the substrate after the source/drain regions have been formed to adjust a threshold voltage of the transistor.

Optionally, the first implantation process includes forming a dielectric layer on the substrate after the gate structure and the source/drain regions are formed, wherein the dielectric layer covers the source/drain regions and has a surface that is substantially flush (coplanar) with a top surface of the gate structure, and providing first dopants into the substrate through the gate structure and the dielectric layer to adjust the threshold voltage of the transistor.

Alternatively, the first implantation process includes forming a dielectric layer on the substrate after the gate structure and the source/drain regions are formed, wherein the dielectric layer covers the source/drain regions and has a surface that is substantially flush (coplanar) with a top surface of the gate structure, and removing the gate or the gate structure to form an opening, wherein the opening exposes a surface area of the gate oxide layer or a surface area of the substrate under the gate structure. The first implantation process further includes providing dopants (i.e., ions) into the substrate through the opening to adjust the threshold voltage of the transistor.

Optionally, the opening is filled with a metallic material to form a metal gate structure.

Optionally, the transistor is an NMOS transistor, the dopants are p-type dopants (ions) comprising boron ions, the dopants have an implanting energy ranging from about 1 KeV to about 12 KeV and an implanting angle ranging from about 0 degree to about 11 degree, and a concentration ranging from about 1E12 atom/cm³ to about 4E13 atom/cm³.

Optionally, the transistor is a PMOS transistor, the dopants are p-type dopants comprising phosphorus ions, the dopants have an implanting energy ranging from about 5 KeV to about 25 KeV and an implanting angle ranging from about 0 degree to about 9 degree, and a concentration ranging from about 1E12 atom/cm³ to about 4E13 atom/cm³.

In an embodiment, forming the well region includes performing a second implantation process into the substrate, and performing a first heat treatment at a temperature ranging from about 700° C. to about 1500° C. to the substrate doped with second ions (i.e., dopants).

In an embodiment, forming the source/drain regions includes performing a third ion implantation process and a second heat treatment at a temperature ranging from about 700° C. to about 1500° C. to the substrate to form the source/drain regions at the opposite sides of the gate structure.

In an embodiment, forming the source/drain regions includes performing a fourth ion implantation process and a third heat treatment to the substrate at the opposite sides of the gate structure to form lightly doped regions at the opposite sides of the gate structure, forming spacers on sidewalls of the gate structure, and performing a fifth ion implantation process and a fourth heat treatment at a temperature ranging from about 700° C. to about 1500° C. to the substrate at the opposite sides of the spacers to form heavily doped regions at the opposite sides of the gate structure, wherein the lightly doped regions and the heavily doped regions together form the source/drain regions.

Optionally, the method further includes performing a sixth ion implantation process and a fifth heat treatment at a temperature ranging from about 700° C. to about 1500° C. to the substrate at the opposite sides of the gate structure to form a pocket implantation region in the substrate at the opposite sides of the gate structure.

It should be noted that the terms “first”, “second”, “third”, “fourth”, “fifth”, “sixth” are used to differentiate the different implantation processes and heat treatment steps used in the method disclosed herein. They do not necessarily determine the sequential order of the processes performed in the invention. For example, the first implantation process is performed after the source/drain regions have been formed. As known in the art, source/drain regions of a MOS transistor can be formed by doping regions of the substrate adjacent to a gate structure. Accordingly, multiple implantation processes may precede the first implantation process recited herein.

Compared with the prior art, embodiments of the present invention provide following advantages and benefits.

The first ion implantation process for adjusting the threshold voltage is performed after the source/drain regions are formed, which may reduce the impact to the diffusion of the first ions caused by the heat treatments performed before the first ion doping (also referred as ion implantation process). The majority of the first ions (also referred as dopants herein) may be distributed near the surface of the substrate, and the number of the first ions diffusing into the internal part of the substrate is reduced, which may reduce the junction capacitance between the source/drain regions and the substrate, and further reduce the junction leaking current. The reduction in junction capacitance and junction leakage current increases the operation speed and the performance of the transistor.

In an embodiment, the first dopants may be provided into the substrate through the gate structure and the dielectric layer having a surface that is substantially coplanar with a top surface of the gate structure, which may improve the implanting accuracy of the ion implantation process.

In another embodiment, the first dopants may be provided into the substrate that is exposed by an opening in the gate structure to adjust the threshold voltage. Implanting through the opening may reduce the implanting energy and improve the accuracy of the first ion implantation process.

In yet another embodiment, the substrate is subjected to a heat treatment following the first ion implantation process at a temperature ranging from about 400° C. to about 500° C. in the event that the first ion implantation process is provided into the substrate through the opening of the gate structure.

Embodiments of the present invention provide another method for forming a transistor that includes a substrate, a well region in the substrate, a gate dielectric layer on the well region, and a gate structure on the gate dielectric layer. The method sequentially includes performing a first ion implantation to the substrate at opposite sides of the gate structure to form lightly doped source/drain regions, performing a second ion implantation to the substrate at opposite sides of the gate structure to form highly doped source/drain regions, forming a dielectric layer over the substrate, and performing a third ion implantation to the substrate through the dielectric layer and the gate structure to adjust a threshold voltage of the transistor, wherein the dielectric layer has a surface that is substantially coplanar with a top surface of the gate structure. The method further includes subjecting the substrate to a heat treatment after each of the first and second ion implantations at a temperature ranging from about 700° C. to about 1500° C.

In an embodiment, the method further includes removing a portion of the gate structure to expose a surface area of the gate dielectric layer prior to performing the third ion implantation. An another embodiment, the method includes removing the gate structure and the gate dielectric layer to expose a surface of the substrate prior to performing the third ion implantation. Additionally, the method includes heating the substrate after performing the third ion implantation to a temperature from about 400° C. to about 500° C.

### BRIEF DESCRIPTION OF THE DRAWINGS

FIG. 1 to FIG. 3 are schematic cross-sectional views of intermediate structures illustrating a method for forming a transistor, as known in the prior art;

FIG. 4 is a flow chart of a method for forming a transistor according to an embodiment of the present invention; and

FIG. 5 to FIG. 11 are schematic cross-sectional views of intermediate structures illustrating a method for forming a transistor according to an embodiment of the present invention.

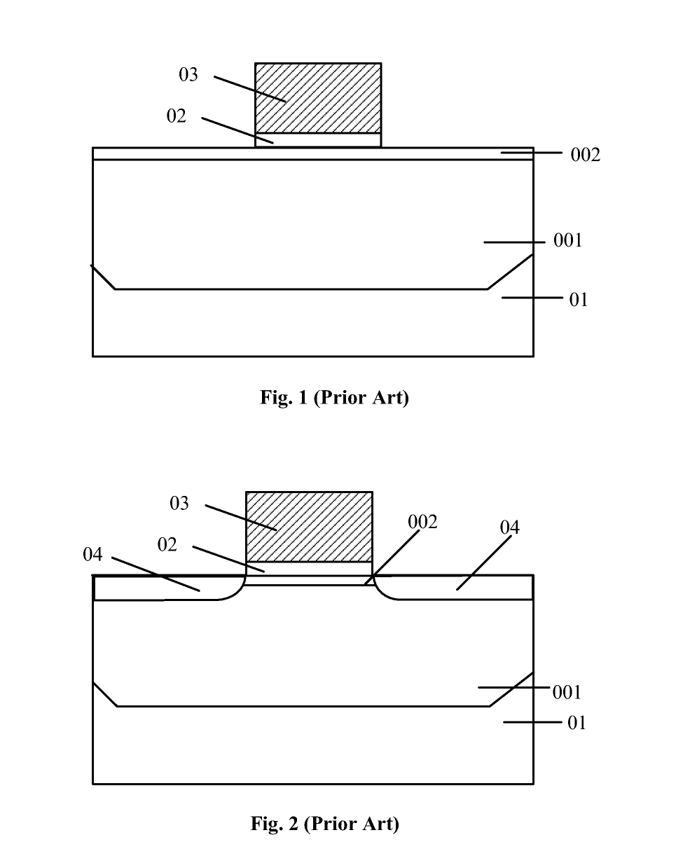

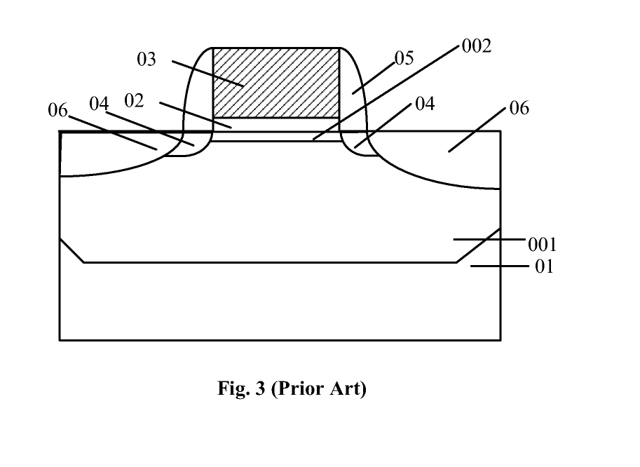

### DETAILED DESCRIPTION OF THE INVENTION

Inventor of the present invention had conducted numerous experiments and measurements, and discovered that ions (dopants) for adjusting the threshold voltage only need to be distributed in a portion of the substrate which is under the gate oxide layer and close to the surface of the substrate. However, in the prior art, the ions for adjusting the threshold voltage are implanted prior to forming the gate structure and forming the source/drain (S/D) regions. Those conventional methods require processes operating in high temperature environments or heat treatments, which may enhance the diffusion of the ions for adjusting the threshold voltage, make the ions diffuse deeper into the internal part of the substrate, enlarge the junction capacitance between the source/drain regions and the substrate, increase the junction leaking current, therefore lowers the operation speed and the performance of the transistor.

In order to solve these problems, an embodiment of the present invention provides a method for forming a transistor having lower junction capacitance and junction leakage current. The method includes providing a substrate, forming a well region in the substrate, forming a gate structure on a surface area of the well region, wherein the gate structure includes a gate oxide layer and a gate locating on a surface of the gate oxide layer, forming source/drain regions in the substrate at opposite sides of the gate structure, and performing a first ion implantation process into the substrate after the formation of the source/drain regions to adjust a threshold voltage of the transistor.

In an embodiment, the first ion implantation process for adjusting the threshold voltage is performed after the source/drain regions are formed, which may reduce the impact to the diffusion of the first ions caused by the heat treatments performed before the first ion implantation process. The majority of the first ions may be distributed near the surface of the substrate, and the number of the first ions diffusing into the internal part of the substrate is reduced, which may reduce the junction capacitance between the source/drain regions and the substrate, and further may reduce the junction leaking current, therefore, the operation speed of the device is increased and the performance of the transistor is improved.

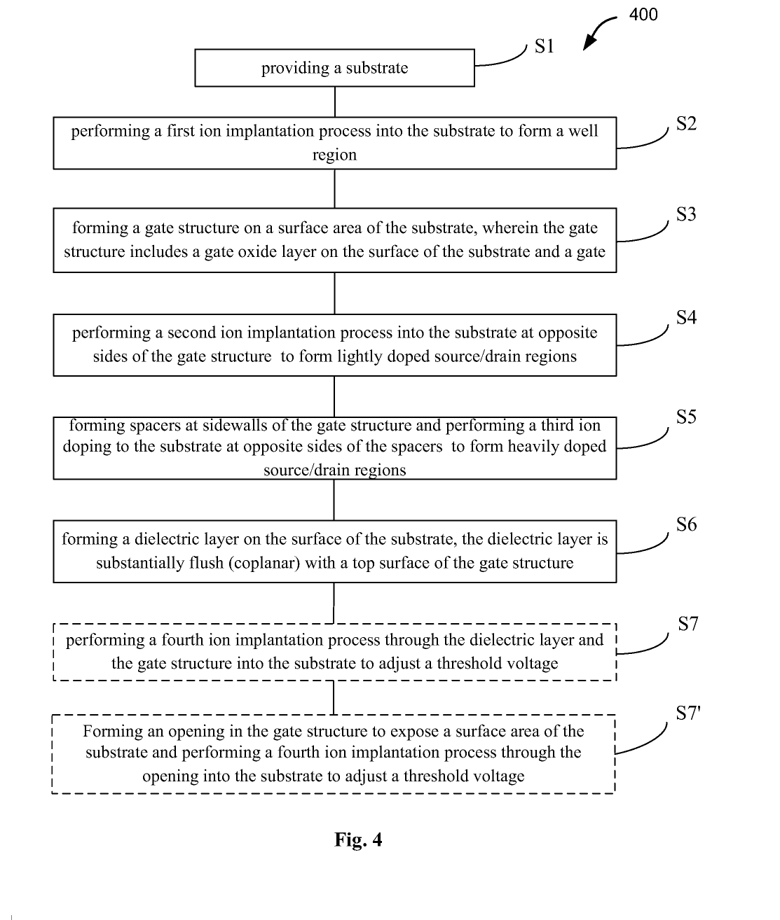

FIG. 4 is a flow chart of a method 400 for forming a transistor according to an embodiment of the present invention. Method 400 includes providing a substrate at step S1, performing a first ion implantation process into the substrate to form a well region at step S2, and forming a gate structure on a surface area of the well region, wherein the gate structure may include a gate oxide layer on the surface of the substrate and a gate over the gate oxide layer at step S3. The method further includes performing a second ion implantation process to the substrate at opposite sides of the gate structure to form lightly doped source/drain regions at step S4, forming spacers on sidewalls of the gate structure and performing a third ion implantation process to the substrate at opposite sides of the spacers to form heavily doped source/drain regions at step S5. The method also includes forming a dielectric layer on the substrate at step S6, wherein the dielectric layer has a surface that is substantially coplanar with a top surface of the gate structure, and performing a fourth ion implantation process into the substrate through the dielectric layer and the gate structure to adjust a threshold voltage at step 7.

In an alternative embodiment, step S7 (shown as S7′ in FIG. 4) may include forming an opening in the gate structure to expose a surface area of the gate oxide layer or a surface area of the substrate prior to performing the fourth ion implantation process to the substrate. In an exemplary embodiment, the opening is formed by removing a portion of the gate structure, the opening defines the exposed surface area of the gate oxide layer or the substrate that is provided with dopants.

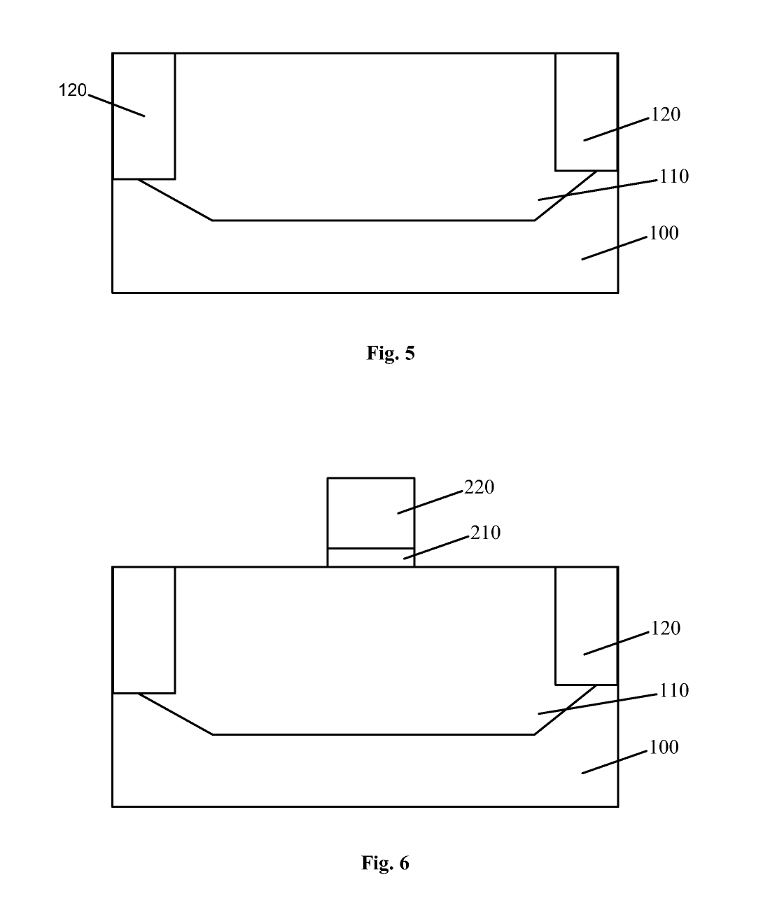

Method 400 will be described in detail below in conjunction with FIG. 5 to FIG. 11

Referring to FIG. 5, a substrate 100 is provided. Substrate 100 is subject to a first ion implantation process (also referred as ion doping herein) to form a well region 110 therein. In the even that the transistor to be formed is an NMOS transistor, the first ions (dopants) are P-type ions, such as boron ions. In the event that the transistor to be formed is a PMOS transistor, the first ions are N-type ions, such as phosphorus ions.

After the first ion implantation process is performed to the substrate 100, substrate 100 may be subjected to a first heat treatment to activate the doped first ions and repair lattice damage caused by the first ion doping. The first heat treatment may include a temperature ranging from about 700° C. to about 1500° C.

Further, isolating structures 120 used for isolating transistor devices may be formed in the substrate 100.

Referring to FIG. 6, a gate structure which includes a gate oxide layer 210 on a surface of the substrate and a gate 220 on a surface of the gate oxide layer 210 is formed on the surface of the substrate 100. Specifically, the gate oxide layer 210 on the surface of the substrate 100 may be formed by applying a thermal oxidation process which may be performed in a high-temperature furnace. The thermal oxidation process may include a temperature ranging from about 700° C. to about 1500° C. In an embodiment, the gate 220 is formed by depositing a polysilicon layer on the gate oxide layer 210.

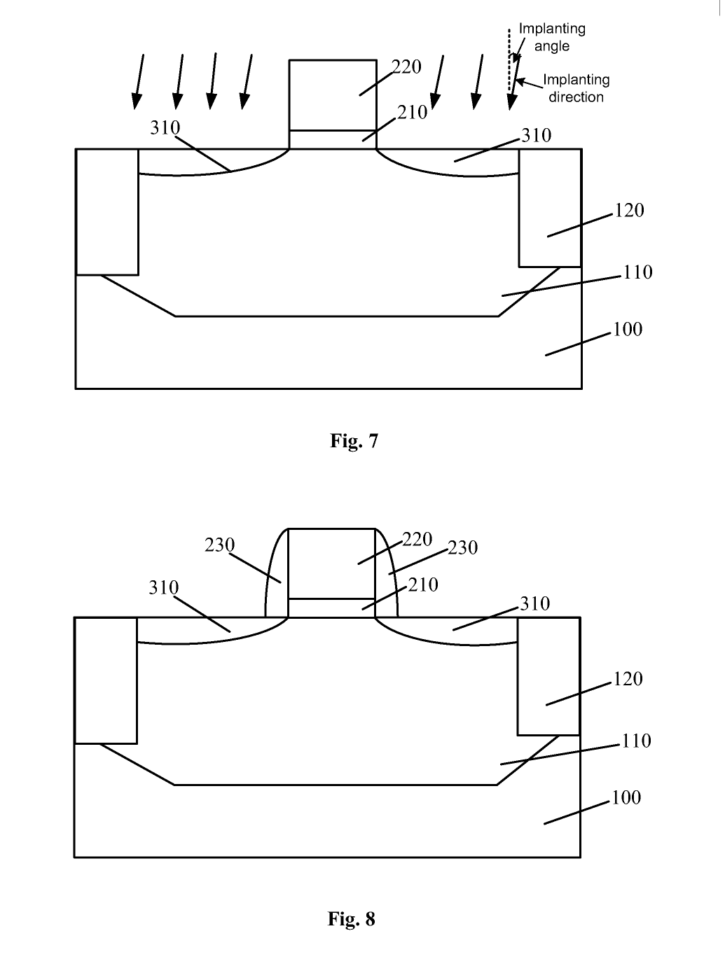

Referring to FIG. 7, using the gate structure as a mask, a second ion implantation process is performed to the substrate 100 at the opposite sides of the gate structure to form lightly doped source/drain regions 310 at opposite sides of the gate structure. In the event that the transistor to be formed is an NMOS transistor, the third ions are N type ions, such as phosphorus ions. In the event that the transistor to be formed is a PMOS transistor, the third ions are P type ions, such as boron ions.

After the second ion implantation process is performed to the substrate 100 at the opposite sides of the gate structure, the substrate 100 may be subjected to a second heat treatment to activate the second doped ions and repair lattice damage caused by the second ion doping. The second heat treatment may include a temperature ranging from about 700° C. to about 1500° C.

Further, a third ion implantation process and a third heat treatment are performed to the substrate 100 to form a pocket implantation region (not shown in the drawings) therein. A temperature of the third heat treatment ranges from about 700° C. to about 1500° C.

Referring to FIG. 8, spacers 230 are formed on sidewalls of the gate structure. In an embodiment, the spacers 230 may be a multi-layer stack including a silicon oxide layer, a silicon nitride layer and a silicon oxide layer (i.e., an ONO structure).

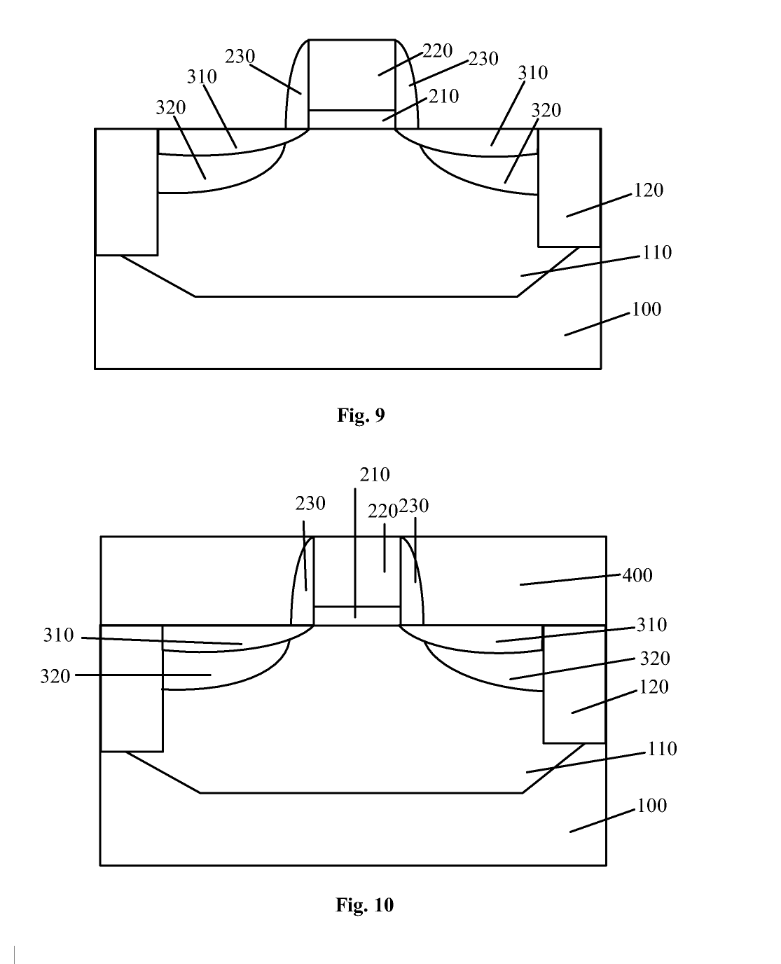

Referring to FIG. 9, using the spacers 230 as a mask, a fourth ion implantation process is performed to the substrate 100 to form heavily doped source/drain regions 320 at the opposite sides of the gate structure. In an embodiment, the lightly doped source/drain regions 310 and the heavily doped source/drain regions 320 together form the source/drain regions.

In an embodiment, if the transistor to be formed is an NMOS transistor, the fourth ions are N type ions, such as phosphorus ions. In another embodiment, if the transistor to be formed is a PMOS transistor, the fourth ions are P type ions, such as boron ions.

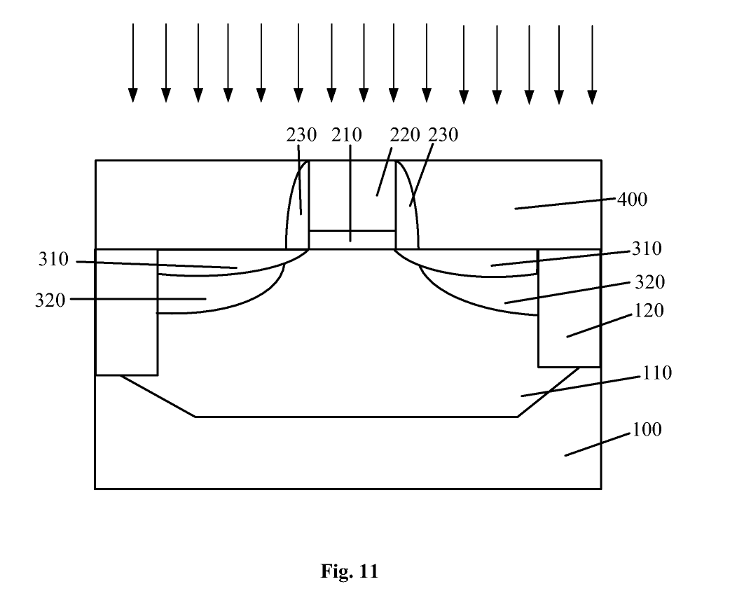

Referring to FIG. 10, a dielectric layer 400 is formed on the substrate 100. The dielectric layer 400 covers a surface of the substrate 100 and is substantially flush (coplanar) with a top surface of the gate structure. In an embodiment, the dielectric layer 400 may be one of silicon oxide, silicon nitride, or a combination thereof.

Referring to FIG. 11, a fifth ion implantation process is performed to the substrate 100 through the dielectric layer 400 and the gate structure to adjust a threshold voltage of the transistor.

In an embodiment, if the transistor is an NMOS transistor, the fifth ions are N type ions, such as boron ions. The fifth ion doping includes an implanting energy ranging from about 1 KeV to about 12 KeV, and an implanting angle ranging from about 0 degree to about 11 degree. The fifth ions include a concentration ranging from about 1E12 atom/cm³ to about 4E13 atom/cm³. The implanting angle is an angle formed between the implanting direction and the normal line of the surface of the substrate 100.

In another embodiment, if the transistor is a PMOS transistor, the fifth ions are P type ions, such as phosphorus ions. The fifth ion doping includes an implanting energy ranging from about 5 KeV to about 25 KeV, and an implanting angle ranging from about 0 degree to about 9 degree. The fifth ions include a concentration ranging from about 1E12 atom/cm³ to about 4E13 atom/cm³. The implanting angle is an angle formed between the implanting direction and the normal line vertically to the surface of the substrate 100.

In a specific embodiment, the transistor is a PMOS transistor, the fifth ions are phosphorus ions, the implanting energy is about 10 KeV, the concentration of the first ions is about 1E13 atom/cm³, and the implanting angle is about 0 degree.

In an embodiment, the fifth ion doping (also referred as implantation process herein) adapted for adjusting the threshold voltage is performed after the source/drain regions are formed, which may reduce the impact to the diffusion of the fifth ions. The impact to the diffusion of the fifth ions is caused by the heat treatments performed before the fifth ion doping. The heat treatments performed before the fifth ion doping may includes the heat treatment for forming the well region 110, the heat treatment for forming the source/drain regions which include the lightly doped source/drain regions 310 and the heavily doped source/drain regions 320, and the heat treatment for forming the pocket implantation region. Further, the impact to the diffusion of the fifth ions may also be caused by high temperature environments included in processes performed before the fifth ion doping, such as the high temperature environment in a furnace in which the gate oxide layer 210 is formed.

In light of the foregoing, the impact to the diffusion of the fifth ions caused by the heat treatments performed before the fifth ion doping is reduced. The majority of the fifth ions may be distributed near the surface of the substrate, and the number of the fifth ions diffusing into the internal part of the substrate may be reduced. That results in a reduction of the junction capacitance between the source/drain regions and the substrate and a reduction in the junction leaking current. As consequence, the operation speed of the transistor is increased and the performance thereof is improved.

Furthermore, the fifth ion doping is performed to the substrate 100 through the gate structure and the dielectric layer 400 whose surface is substantially flush (coplanar) with the top surface of the gate structure, this structure may improve the implanting accuracy of the ion doping.

In an embodiment, an opening is formed by removing the gate 220 after the dielectric layer 410 is formed, and a surface area of the gate oxide layer 210 is exposed by the opening. The fifth ion doping is performed to the substrate 100 through the gate oxide layer 210 so as to adjust the threshold voltage. In subsequent processes, the opening is filled with a metallic material to form semiconductor structures, such as a metal gate structure.

In another embodiment, an opening is formed by removing the gate structure including the gate oxide layer 210 after the dielectric layer 410 is formed to expose a surface area of the substrate 100 under the gate structure. The fifth ion doping is performed to the substrate 100 to adjust the threshold voltage. Performing the fifth ion doping directly to the exposed substrate may prevent damaging the gate oxide layer. In subsequent processes, the opening is filled with a metallic material to form semiconductor structures, such as a metal gate structure.

The fifth ion doping is performed to adjust the threshold voltage after the gate or the gate structure is removed, which may reduce the implanting energy and improve the accuracy of the fifth ion doping.

The substrate may further be subjected to a heat treatment to activate the fifth ions and repair lattice damage caused by the fifth ion doping. In an embodiment, the heat treatment includes a temperature ranging from about 400° C. to about 500° C.

In an embodiment, the fifth ions may be activated by heat treatments in subsequent processes such as forming interconnecting structures. Temperatures of the heat treatments after the source/drain regions are formed are generally lower and range from about 400° C. to about 500° C. These heat treatments can activate the fifth ions and repair lattice damage in the substrate 100 caused by the fifth ion doping. In addition, the diffusion of the fifth ions in the substrate occurs more slowly due to the lower annealing temperature.

Compared with the prior art, embodiments of the present invention provide the following advantages and benefits.

The fifth ion doping for adjusting the threshold voltage is performed after the source/drain regions are formed, which may reduce the impact to the diffusion of the fifth ions caused by the heat treatments performed before the fifth ion doping. The majority of the fifth ions may be distributed near the surface of the substrate, and the number of the fifth ions diffusing into the internal part of the substrate is reduced, which may reduce the junction capacitance between the S/D regions and the substrate, and further reduce the junction leaking current, therefore, the operation speed of the devices is increased and the performance thereof is improved.

Furthermore, the fifth ion doping is performed to the substrate through the gate structure and the dielectric layer which is substantially flush with the gate structure, which may improve the accuracy of the first ion doping.

In addition, the first ion doping is performed to the substrate which is exposed by the trench so as to adjust the threshold voltage, which may reduce the implanting energy and improve the accuracy of the first ion doping.

The preferred embodiments of the present invention have been described for illustrative modification purposes, and those skilled in the art will appreciate that various modifications, additions and substitutions are possible, without departing from the scope and spirit of the invention as disclosed in the claims.

What is claimed is:

1. A method for forming a transistor, comprising:
providing a substrate;
forming a well region in the substrate;
forming a gate structure on a surface of the well region, the gate structure including a gate oxide layer on the surface of the well region and a gate on the gate oxide layer;
forming source/drain regions in the substrate at opposite sides of the gate structure; and
performing a first ion implantation process to the substrate after the source/drain regions are formed.

2. The method according to claim 1, wherein the first ion implantation process comprises:
forming a dielectric layer after the gate structure and the source/drain regions are formed, wherein the dielectric layer covers surfaces of the source/drain regions and is substantially coplanar with a top surface of the gate structure; and
providing first dopants into the substrate through the gate structure and the dielectric layer to adjust a threshold voltage of the transistor.

3. The method according to claim 1, wherein the first ion implantation process comprises:
forming a dielectric layer after the gate structure and the source/drain regions are formed, wherein the dielectric layer covers surfaces of the source/drain regions and is substantially flush with a surface of the gate structure;
removing the gate or the gate structure to form an opening, the opening exposing a surface of the gate oxide layer or a surface of the substrate under the gate structure; and
providing first dopants into the substrate to adjust a threshold voltage of the transistor.

4. The method according to claim 3, wherein the opening is filled with a metallic material to form a metal gate structure.

5. The method according to claim 3, wherein the first dopants comprise p-type dopants having an implanting energy ranging from about 1 KeV to about 12 KeV and an implanting angle ranging from about 0 degree to about 11 degrees, and a concentration ranging from about 1E12 atom/cm³ to about 4E13 atom/cm³.

6. The method according to claim 5, wherein the p-type dopants comprise boron ions.

7. The method according to claim 3, wherein the first dopants are n-type dopants having an implanting energy ranging from about 5 KeV to about 25 KeV and an implanting angle ranging from about 0 degree to about 9 degrees, and a concentration ranging from about 1E12 atom/cm³ to about 4E13 atom/cm³.

8. The method according to claim 7, wherein the n-type dopants comprise phosphorus ions.

9. The method according to claim 1, wherein forming the well region comprises:
performing a second ion implantation process to the substrate to dope the substrate with second dopants; and
subjecting the substrate to a first heat treatment at a temperature ranging from about 700° C. to about 1500° C.

10. The method according to claim 1, wherein forming the source/drain regions comprises:
performing a third ion implantation process to the substrate; and
subjecting the substrate to a second heat treatment at a temperature ranging from about 700° C. to about 1500° C. to form lightly doped regions at the opposite sides of the gate structure.

11. The method according to claim 10 further comprising:
forming spacers on sidewalls of the gate structure; and
performing a fourth ion implantation process and a third heat treatment to the substrate adjacent to the spacers to form heavily doped regions at the opposite sides of the gate structure, wherein the lightly doped regions and the heavily doped regions constitute the source/drain regions.

12. The method according to claim 11 further comprising:
performing a fifth ion implantation process to the substrate; and
subjecting the substrate to a fourth heat treatment at a temperature ranging from about 700° C. to about 1500° C. to form a pocket implantation region in the substrate at the opposite sides of the gate structure.

13. The method according to claim 1 further comprising:
after performing the first ion implantation process, heating the substrate at a temperature ranging from 400° C. to about 500° C.

14. A method for forming a transistor comprising a substrate, a well region in the substrate, a gate dielectric layer on the well region, a gate structure on the gate dielectric layer, the method sequentially comprising:
performing a first ion implantation into the substrate at opposite sides of the gate structure to form lightly doped source/drain regions;
forming spacers on sidewalls of the gate structure;
performing a second ion implantation into the substrate at opposite sides of the gate structure to form heavily doped source/drain regions;
forming a dielectric layer over the substrate, the dielectric layer having a surface substantially coplanar with a top surface of the gate structure; and
performing a third ion implantation into the substrate.

15. The method according to claim 14, wherein performing the third ion implantation comprises:
providing dopants through the dielectric layer and the gate structure into the substrate to adjust a threshold voltage of the transistor.

16. The method according to claim 14, wherein performing the third ion implantation comprises:
removing the gate structure to form an opening to expose a surface area of the substrate; and
providing dopants through the opening into the substrate to adjust a threshold voltage of the transistor.

17. The method according to claim 16, wherein the dopants comprise p-type dopants having an implanting energy ranging from about 1 Key to about 12 Key and an implanting angle ranging from about 0 degree to about 11 degrees, and a concentration ranging from about 1E12 atom/cm³ to about 4E13 atom/cm³.

18. The method according to claim 16, wherein the dopants comprise n-type dopants having an implanting energy ranging from about 5 Key to about 25 Key and an implanting angle ranging from about 0 degree to about 9 degrees, and a concentration ranging from about 1E12 atom/cm³ to about 4E13 atom/cm³.

19. The method according to claim 14 further comprising heating the substrate after each of the first and second ion implantation before the performing the third ion implantation at a temperature ranging from about 700° C. to about 1500° C.

20. The method according to claim 14 further comprising heating the substrate after the third ion implantation at a temperature ranging from about 400° C. to about 500° C.
